(19) United States
(12) Patent Application Publication
(10) Pub. No.: US 2026/0107730 A1
(43) Pub. Date: Apr. 16, 2026

(54) COOLANT CONDUIT AND WAFER-COOLING APPARATUS INCLUDING THE SAME

(71) Applicant: TAIWAN SEMICONDUCTOR MANUFACTURING COMPANY, LTD., Hsinchu (TW)

(72) Inventors: Jhih-Ren LIN, Hsinchu (TW); Wei-Da CHEN, Hsinchu (TW); Yu-Ting TSAI, Hsinchu (TW); Wen-Hsun TSAI, Hsinchu (TW); Hsin-Jung CHANG, Hsinchu (TW)

(73) Assignee: TAIWAN SEMICONDUCTOR MANUFACTURING COMPANY, LTD., Hsinchu (TW)

(21) Appl. No.: 18/913,104

(22) Filed: Oct. 11, 2024

(51) Int. Cl. H01L 21/67

(52) U.S. Cl. CPC H10P 72/0434

(57) ABSTRACT

A coolant conduit includes at least one tubular wall and at least one arcuate slit hole. The arcuate slit hole is formed in an outer wall surface of the tubular wall and extends from the outer wall surface into an inner wall surface of the tubular wall. The arcuate slit hole has a height and a width. A ratio of the width to the height is greater than about 1.

### BACKGROUND

A wafer subjected to a high temperature process (for example, but not limited to, a wet etching process at an elevated temperature) is generally required to be cooled before the wafer is further processed or stored. This is due to the fact that at an elevated temperature, a wafer and semiconductor devices formed on the wafer are very sensitive to moisture, organic carbon, and a variety of other gases (for example, but not limited to, oxygen gas), and thus may react with the moisture, the organic carbon, and/or and the gases to form contaminants.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view illustrating a wafer-cooling apparatus including a coolant conduit assembly formed with a coolant conduit in accordance with some embodiments.

FIG. 2 is a schematic perspective view illustrating the coolant conduit assembly formed with the coolant conduit shown in FIG. 1.

FIG. 3 is an enlarged view taken from the area marked by a dotted box (B1) in FIG. 1, and schematically shows a portion of the coolant conduit.

FIG. 4 is another enlarged view of FIG. 1, and schematically shows a portion of the coolant conduit.

FIG. 5 is a schematic perspective view illustrating a portion of a tubular wall included in the coolant conduit shown in FIG. 2.

FIG. 6 is a schematic sectional view of the portion of the tubular wall shown in FIG. 5.

FIG. 7 is a schematic sectional view illustrating a portion of the coolant conduit shown in FIG. 2.

FIG. 8 is a schematic view illustrating a portion of a coolant conduit in accordance with some alternative embodiments.

FIG. 9 is a schematic view illustrating a portion of a coolant conduit in accordance with some further alternative embodiments.

FIG. 10 is a schematic view illustrating a flow rate distribution of a coolant gas within a chamber of a wafer-cooling apparatus including the coolant conduit shown in FIG. 8.

FIG. 11 is a schematic view illustrating a flow rate distribution of a coolant gas within a chamber of a wafer-cooling apparatus including the coolant conduit shown in FIG. 2.

FIG. 12 is a schematic view illustrating a heat convection coefficient distribution on a wafer disposed in a chamber of a wafer-cooling apparatus including the coolant conduit shown in FIG. 8.

FIG. 13 is a schematic view illustrating a heat convection coefficient distribution on a wafer disposed in a chamber of a wafer-cooling apparatus including the coolant conduit shown in FIG. 2.

FIG. 14 is a schematic view illustrating a heat convection coefficient distribution on a wafer disposed in a chamber of a wafer-cooling apparatus including a coolant conduit in accordance with some embodiments.

FIG. 15 is a schematic view illustrating a heat convection coefficient distribution on a wafer disposed in a chamber of a wafer-cooling apparatus including a coolant conduit in accordance with some alternative embodiments.

FIG. 16 is a schematic view illustrating a heat convection coefficient distribution on a wafer disposed in a chamber of a wafer-cooling apparatus including a coolant conduit in accordance with some further alternative embodiments.

FIG. 17 is a graph showing comparison of heat convection coefficient distributions on wafers analyzed using the coolant conduits shown in FIGS. 3, 8, and 9.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “upper,” “lower,” “uppermost,” “lowermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

A wafer subjected to a high temperature process (for example, but not limited to, a wet etching process at an elevated temperature) is required to be cooled in a wafer-cooling apparatus before the wafer is subjected to a subsequent process (for example, but not limited to, a baking process). In addition, the wafer subjected to the baking process is required to be cooled in the wafer-cooling apparatus before the wafer is subjected to a further subsequent process (for example, a metal-filling process for forming conductive interconnects). This is due to the fact that at an elevated temperature, a wafer and semiconductor devices formed on the wafer are very sensitive to moisture, organic carbon, and a variety of other gases (for example, but not limited to, oxygen gas), and thus may react with the moisture, the organic carbon, and/or the gases to form contaminants. In addition, with rapid development of semiconductor manufacturing technology, continual reduction in minimum feature sizes is a trend in the semiconductor industry. When a wafer subjected to a high temperature process (for example, but not limited to, a wet etching process at an elevated temperature) is not cooled sufficiently, conductive interconnects (for example, but not limited to, metal lines) exposed from openings of a dielectric layer formed on the conductive interconnects may be contaminated by moisture, organic carbon, and other gases (for example, but not limited to, oxygen gas), which may induce metal loss defect, i.e., failure of electric interconnection between the conducive interconnects and another conductive interconnects (for example, but not limited to, contact vias) formed in the openings.

The present disclosure is directed to a wafer-cooling apparatus including a coolant conduit assembly formed with a coolant conduit that is formed with a plurality of arcuate slit holes and includes a plurality of flow limiters, so that a plurality of wafers disposed in the wafer-cooling apparatus can be cooled sufficiently.

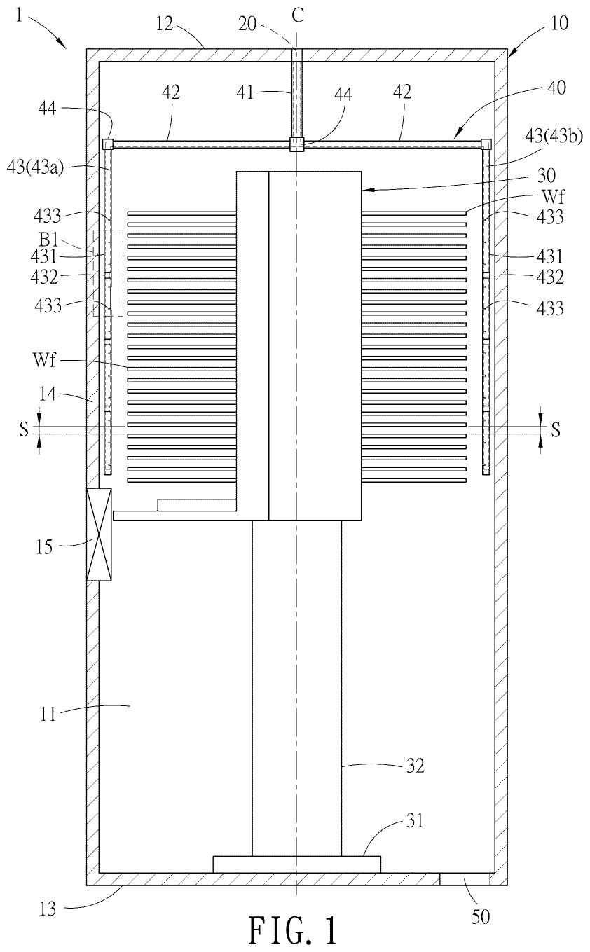

FIG. 1 is a schematic view illustrating a wafer-cooling apparatus 1 in accordance with some embodiments. The wafer-cooling apparatus 1 includes a chamber 10, a gas inlet 20, a wafer boat 30, and a coolant conduit assembly 40.

The chamber 10 has an accommodation space 11 extending in a direction of a central axis (C) to terminate at an upper end wall 12 of the chamber 10. The chamber 10 further includes a lower end wall 13 and a surrounding wall 14 disposed between and connected to the upper end wall 12 and the lower end wall 13, so that the wafer boat 30 is surrounded by the surrounding wall 14 of the chamber 10. The upper end wall 12, the lower end wall 13, and the surrounding wall 14 cooperatively define the accommodation space 11. In some embodiments, the chamber 10 may be made of, for example, but not limited to, a metallic material or a quartz material. In some embodiments, the metallic material may include, for example, but not limited to, aluminum or stainless steel. Other suitable materials for the chamber 10 are within the contemplated scope of the present disclosure. In some embodiments, the chamber 10 is configured as a cylindrical shape. Other suitable geometrical shapes for the chamber 10 are within the contemplated scope of the present disclosure.

The coolant inlet 20 is disposed in the upper end wall 12 of the chamber 10, and is connected to the coolant conduit assembly 40, so that the coolant inlet 20 is in fluid communication with the accommodation space 11 of the chamber 10 through the coolant conduit assembly 40. The coolant inlet 20 is configured for introducing a coolant gas into the coolant conduit assembly 40 through the coolant inlet 20. The coolant gas is supplied from a coolant gas supplier (not shown) into the coolant inlet 20. In some embodiments, the coolant gas includes inert gas, for example, but not limited to, helium gas, neon gas, argon gas, krypton gas, xenon gas, radon gas, nitrogen gas, or combinations thereof. Other suitable inert gases for the coolant gas are within the contemplated scope of the present disclosure.

An exhaust outlet 50 is disposed in the lower end wall 13 of the chamber 10, and is in fluid communication with the accommodation space 11 of the chamber 10. The exhaust outlet 50 is configured for exhausting the coolant gas and any other gas (for example, moisture, oxygen gas, or the like) from the accommodation space 11 of the chamber 10 to an exterior of the chamber 10 through the exhaust outlet 50.

The wafer boat 30 is disposed in the accommodation space 11 of the chamber 10 to mount a plurality of wafers (Wf) displaced from one another by a plurality of interval spaces(S) along the central axis (C). The wafer boat 30 is formed with a plurality of support members (not shown) in an upper portion of the wafer boat 30. The support members horizontally and respectively support the plurality of wafers (Wf) in a state where centers of the wafers (Wf) are aligned with one another in the direction of the central axis (C). A lower portion of the wafer boat 30 is configured with a base 31 disposed on the lower end wall 13 of the chamber 10 and a shaft 32 connected to the upper portion of the wafer boat 30. The shaft 32 is movable up and down through the base 31 and the lower end wall 13 of the chamber 10 in the direction of the central axis (C), so as to permit the wafers (Wf) to be charged to the support members of the wafer boat 30 and to be discharged from the support members of the wafer boat 30.

A boat elevator (not shown) is installed below and connected to the shaft 32 of the wafer boat 30 for raising and lowering the wafer boat 30 through the base 31 and the lower end wall 13 of the chamber 10 when the wafers (Wf) are to be charged to the support members of the wafer boat 30 or to be discharged from the support members of the wafer boat 30. In some embodiments, the boat elevator is made up of, for example, but not limited to, motor-driven feed screw shaft device or bellows. Other suitable devices for the boat elevator are within the contemplated scope of the present disclosure.

A gate valve 15 is disposed at an intermediate portion of the chamber 10 and is used to open and close the chamber 10. The gate valve 15 is opened when the wafers (Wf) are be charged to the support members of the wafer boat 30 or to be discharged from the support members of the wafer boat 30. The gate valve 15 is closed before the wafers (Wf) charged to the support members of the wafer boat 30 are to be cooled by the coolant conduit assembly 40.

The coolant conduit assembly 40 is disposed in the chamber 40, and includes an inlet conduit 41, a plurality of interconnecting conduits 42, a plurality of coolant conduits 43, and a plurality of connectors 44. The inlet conduit 41 is connected to the interconnecting conduits 42 through a corresponding one of the connectors 44, and is also connected to the coolant inlet 20. Each of the interconnecting conduits 42 is connected to a corresponding one of the coolant conduits 43 through a corresponding one of the connecters 44. The coolant conduits 43 are angularly spaced apart from one another. In some embodiments, each of the connectors is configured as, for example, but not limited to, a piping fitting. In some embodiments, the inlet conduit 41 and the interconnecting conduits 42 may be made of, for example, but not limited to, a metallic material (for example, but not limited to, aluminum or stainless steel). Other suitable materials for the inlet conduit 41 and the interconnecting conduits 42 are within the contemplated scope of the present disclosure. In some embodiments, the connecters 44 may be made of, for example, but not limited to, a metallic material (for example, but not limited to, aluminum or stainless steel). Other suitable materials for the connectors 44 are within the contemplated scope of the present disclosure.

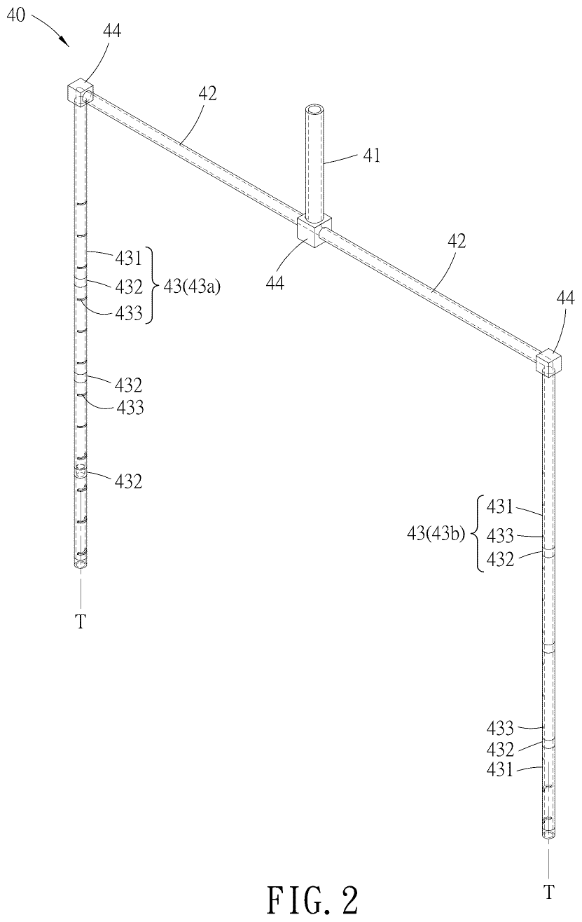

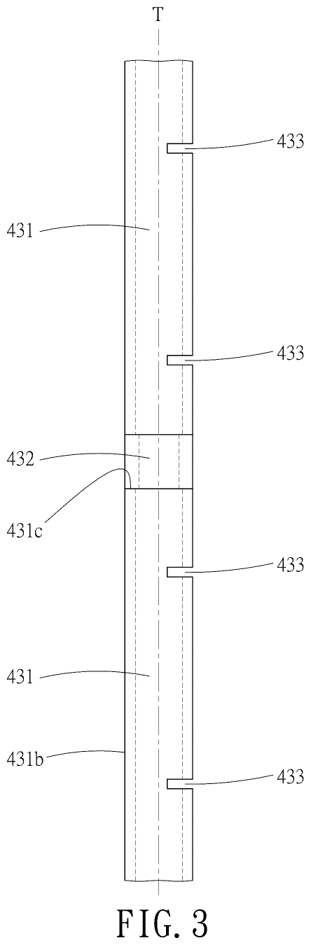

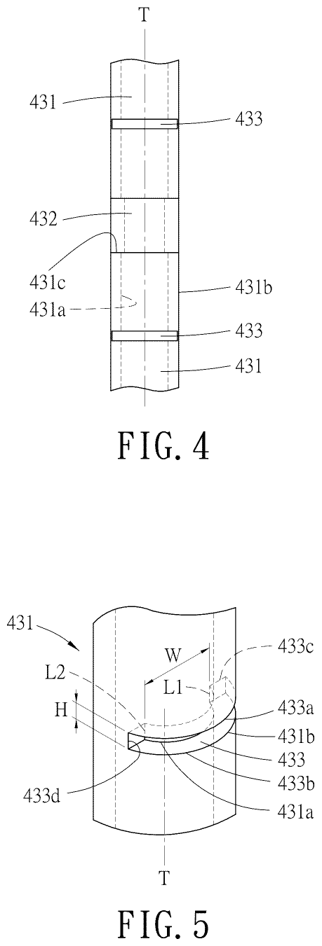

FIG. 2 is a schematic perspective view illustrating the coolant conduit assembly 40 formed with the coolant conduits 43, and FIGS. 3 and 4 are enlarged views schematically showing a portion of one of the coolant conduits 43. In some embodiments, the coolant conduit assembly 40 includes a first coolant conduit 43a and a second coolant conduit 43b, which are disposed to be diametrically opposite to each other. Each of the first coolant conduit 43a and the second coolant conduit 43b includes a plurality of tubular walls 431, a plurality of flow limiters 432, and a plurality of arcuate slit holes 433. In some embodiments, the tubular walls 431 may be made of, for example, but not limited to, a metallic material (for example, but not limited to, aluminum or stainless steel). Other suitable materials for the tubular walls 431 are within the contemplated scope of the present disclosure. In some embodiments, the flow limiters 432 may be made of, for example, but not limited to, a metallic material (for example, but not limited to, aluminum or stainless steel). Other suitable materials for the flow limiters 432 are within the contemplated scope of the present disclosure. The tubular walls 431 are displaced from one another in a direction of a tubular axis (T) of the first coolant conduit 43a (or the second coolant conduit 43b). The flow limiters 432 are alternated with and connected to the tubular walls 431 in the direction of the tubular axis (T) of the first coolant conduit 43a (or the second coolant conduit 43b).

The tubular walls 431 are disposed outwardly and radially from the wafer boat 30 (see FIG. 1) in the chamber 10. As shown in FIGS. 3 and 4, each of the tubular walls 431 includes an inner wall surface 431a and an outer wall surface 431b opposite to each other in radial directions. The inner wall surface 431a surrounds the tubular axis (T) of the first coolant conduit 43a (or the second coolant conduit 43b) and defines a passage extending upwardly to terminate at an upper end surface 431c that is formed with an opening in fluid communication with the coolant inlet 20. Each of the arcuate slit holes 433 is formed in the outer wall surface 431b of a corresponding one of the tubular walls 431 to confront the wafer boat 30 (see FIG. 1).

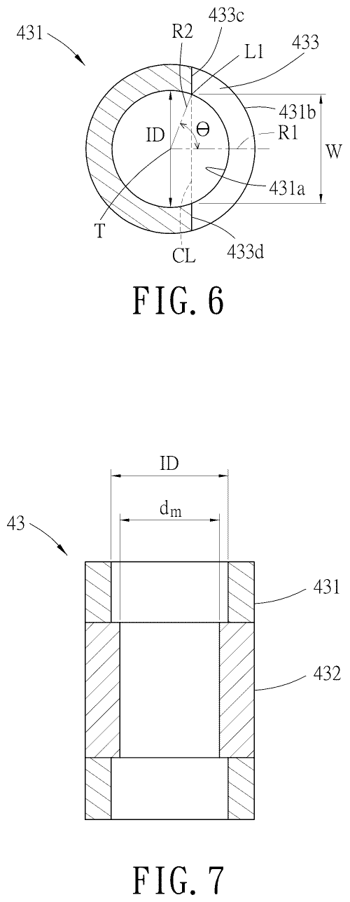

FIG. 5 is a schematic perspective view illustrating a portion of one of the tubular walls 431 shown in FIG. 2, and FIG. 6 is a schematic sectional view of the portion of the one of the tubular walls 431 shown in FIG. 5. Each of the arcuate slit holes 433 extends from the outer wall surface 431b of a corresponding one of the tubular walls 431 into the inner wall surface 431a of the corresponding one of the tubular walls 431 along a first radial line (R1) to be in fluid communication with the accommodation space 11 of the chamber 10 (see FIG. 1). Each of the arcuate slit holes 433 extends along the tubular axis (T) of the first coolant conduit 43a (or the second coolant conduit 43b) to terminate at an upper surface 433a and a lower surface 433b that define a height (H) of each of the arcuate slit holes 433, and extends about the tubular axis (T) of the first coolant conduit 43a (or the second coolant conduit 43b) to terminate at a first side surface 433c and a second side surface 433d. The first side surface 433c forms a first joining line (L1) with the inner wall surface 431a. The second side surface 433d forms a second joining line (L2) with the inner wall surface 431a. The first joining line (L1) and the second joining line (L2) form a chord line (CL) that is perpendicular to the first radial line (R1) and that defines a width (W) of each of the arcuate slit holes 433. In some embodiments, a ratio of the width (W) to the height (H) is greater than about 1. In some embodiments, the ratio of the width (W) to the height (H) is greater than about 1 and less than about 11.5. When the ratio of the width (W) to the height (H) is not greater than 1, the wafers (Wf) disposed in the chamber 10 of the wafer-cooling apparatus 1 cannot be cooled sufficiently. In addition, the arcuate slit holes 433 having the ratio of the width (W) to the height (H) of not less than 11.5 cannot be formed easily by machining. In some embodiments, the first side surface 433c and the second side surface 433d of each of the arcuate slit holes 433 are in a same plane (see FIG. 6). The first joining line (L1) and the tubular axis (T) define a second radial line (R2), and the first radial line (R1) and the second radial line (R2) form an included angle (Θ). In some embodiments, the included angle (Θ) is greater than about 10.5° and less than about 90.5°. When the included angle is less than 10.5° or greater than 90.5°, the wafers (Wf) disposed in the chamber 10 of the wafer-cooling apparatus 1 cannot be cooled sufficiently.

FIG. 7 is a schematic sectional view illustrating a portion of one of the coolant conduits 43 shown in FIG. 2. Each of the tubular walls 431 has an inner diameter (ID). Each of the flow limiters 432 has an inner diameter (dₘ). The inner diameter (dₘ) of each of the flow limiters 432 is smaller than the inner diameter (ID) of each of the tubular walls 431. In some embodiments, a ratio of the inner diameter (dₘ) of each of the low limiters 432 to the inner diameter (ID) of each of the tubular walls 431 is greater than about 0.5 and less than about 1. When the ratio is less than 0.5, the coolant gas may not flow in an entire passage in each of the coolant conduits 43. When the ratio is equal to 1, the flow limiters 432 cannot have a flow-limiting effect.

Referring to FIG. 2, in some embodiments, the flow limiters 432 of the first coolant conduit 43a (or the second coolant conduit 43b) have gradually reduced inner diameters (dₘ) in a downstream direction. In some embodiments, each of the tubular walls 431 of the first coolant conduit 43a (or the second coolant conduit 43b) includes at least one of the arcuate slit holes 433. In some embodiments, each of the tubular walls 431 of the first coolant conduit 43a (or the second coolant conduit 43b) includes about 1 to about 3 of the arcuate slit holes 433. In some embodiments, a total number of the arcuate slit holes 433 formed in the first coolant conduit 43a and the second coolant conduit 43b ranges from about 20 to about 50.

Referring to FIG. 1, in some embodiments, the arcuate slit holes 433 of the first coolant conduit 43a are displaced from one another in a direction of a conduit axis of the first coolant conduit 43a, the arcuate slit holes 433 of the second coolant conduit 43b are displaced from one another in a direction of a conduit axis of the second coolant conduit 43b, the arcuate slit holes 433 of the first coolant conduit 43a are staggered from the arcuate slit holes 433 of the second coolant conduit 43b, each of the arcuate slit holes 433 of the first coolant conduit 43a registers with a corresponding one of the plurality of interval spaces(S) by which the wafers (Wf) mounted on the wafer boat 30 are displaced from one another, and each of the arcuate slit holes 433 of the second coolant conduit 43b registers with a corresponding one of the plurality of interval spaces(S).

A wafer transfer device (not shown) is configured to charge a plurality of the wafers (Wf), which are to be cooled by the wafer-cooling device 1, from a FOUP (a front opening unified pod, not shown) mounted on a mount stand (not shown) to the support members of the wafer boat 30, and to discharge a plurality of the wafers (Wf), after being cooled by the wafer-cooling device 1, from the support members of the wafer boat 30 to the FOUP mounted on the mount stand.

A cap fitter/remover (not shown) is configured to fit and remove a cap on the FOUP. The cap fitter/remover fits or removes the cap on the FOUP mounted on the mount stand, so as to permit a wafer loading/unloading port of the FOUP to be closed or opened.

In some embodiments, after the wafers (Wf) are subjected to a high temperature process (for example, but not limited to, a wet etching process at an elevated temperature), the wafers (Wf) are moved from a chamber, in which the high temperature process is conducted, into the FOUP, and the FOUP, in which the wafers (Wf) are stored, is then transferred to the mount stand by a FOUP transfer device. The cap fitter/remover removes the cap on the FOUP to open the wafer loading/unloading port of the FOUP, and the gate valve 15 of the wafer-cooling apparatus 1 is opened. The wafers (Wf) stored in the FOUP are removed by the wafer transfer device from the FOUP, and are charged to the support members of the wafer boat 30. The wafer transfer device scoops a batch of the wafers (Wf) stored in the FOUP, carries the batch of the wafers (Wf) through the wafer loading/unloading port of the FOUP into the chamber 10 of the wafer-cooling apparatus 1, and charges the batch of the wafers (Wf) to the support members of the wafer boat 30. After the batch of the wafers (Wf) is charged to the support members of the wafer boat 30, the wafer transfer device returns to the FOUP, and charges a next batch of the wafers (Wf) from the FOUP to the support members of the wafer boat 30. By having the wafer transfer device repeating the wafer-charging operation, all of the wafers (Wf) stored in the FOUP are sequentially charged to the support members of the wafer boat 30, and the gate valve 15 of the wafer-cooling apparatus 1 is closed.

Thereafter, the coolant gas (inert gas, for example, but not limited to, helium gas, neon gas, argon gas, krypton gas, xenon gas, radon gas, nitrogen gas, or combinations thereof) supplied from the coolant gas supplier is introduced into the coolant conduit assembly 40 through the coolant inlet 20, and is sprayed through the arcuate slit holes 433 toward the interval spaces(S) among the wafers (Wf) to cool the wafers (Wf) and to carry away moisture, oxygen gas, organic carbon, or the like which remains on the wafers (Wf) (for example, trapped in openings of a dielectric layer formed on the conductive interconnects (such as, metal lines) after the high temperature process), so as to avoid or alleviate the metal loss defect induced by the moisture, the oxygen gas, the organic carbon, or the like.

After the wafers (Wf) are cooled for a predetermined time period or to a predetermined temperature by the coolant gas, the gate valve 15 of the wafer-cooling apparatus 1 is opened. The wafers (Wf) mounted on the support members of the wafer boat 30 are discharged by the wafer transfer device into the FOUP in batches until all of the wafers (Wf) mounted on the support members of the wafer boat 30 are discharged from the support members of the wafer boat 30 and charged into the FOUP. The FOUP, in which the wafers (Wf) are stored, is then transferred by the FOUP transfer device to a chamber in which a subsequent process (for example, but not limited to, a baking process) is to be conducted. After the baking process is finished, the wafers (Wf) are transferred from the chamber, in which the baking processed is conducted, to the mount stand by the FOUP transfer device, and are then charged to the support members of the wafer boat 30 by the wafer transfer device. The wafers (Wf) are subjected to another cooling process by the wafer-cooling apparatus 1. After the another cooling process is completed, the wafers (Wf) are discharged from the support members of the wafer boat 30, and are transferred and charged into the FOUP. The FOUP, in which the wafers (Wf) are stored, are transferred by the FOUP transfer device to another chamber in which a following process (for example, but not limited to, a process for forming contact vias) is to be conducted.

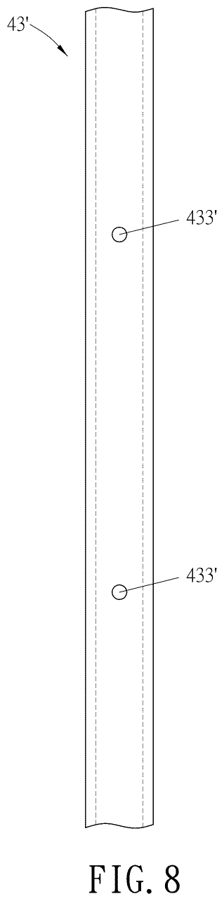

Referring to FIG. 8, in some alternative embodiments, the coolant conduit assembly 40 of the wafer-cooling apparatus 1 includes a plurality of coolant conduits 43′, and each of the coolant conduits 43′ is formed with a plurality of circular holes 433′, instead of the arcuate slit holes 433.

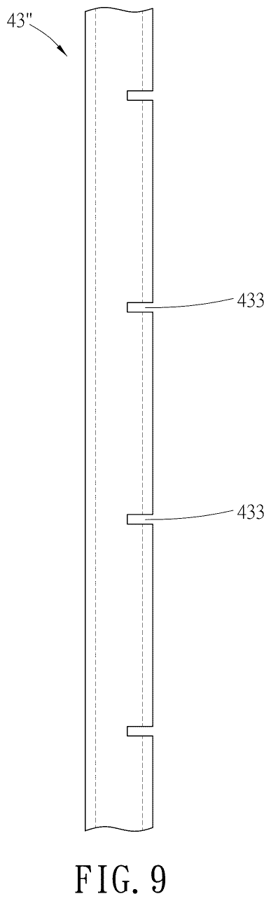

Referring to FIG. 9, in some further alternative embodiments, the coolant conduit assembly 40 of the wafer-cooling apparatus 1 includes a plurality of coolant conduits 43′, and each of the coolant conduits 43′ is formed with a plurality of the arcuate slit holes 433, but is not formed with the flow limiters 432.

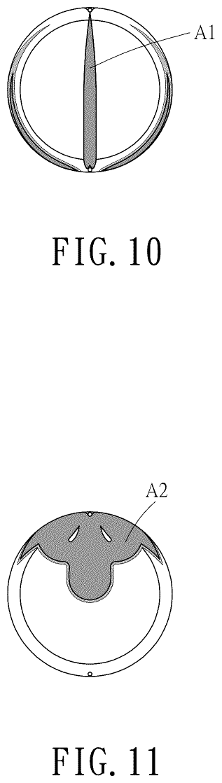

The wafer-cooling apparatus 1 in which the coolant conduit assembly 40 includes the coolant conduits 43′ formed with the circular holes 433′, and the wafer-cooling apparatus 1 in which the coolant conduit assembly 40 includes the coolant conduits 43 which are formed with the arcuate slit hole 433 and which include the flow limiters 432 are subjected to a flow rate distribution analysis and a heat convection coefficient distribution analysis. The results are shown in FIGS. 10 to 13.

FIG. 10 illustrates a flow rate distribution of the coolant gas in the chamber 10 of the wafer-cooling apparatus 1 in which the coolant conduit assembly 40 includes the coolant conduits 43′ formed with the circular holes 433′ (see FIG. 8). FIG. 11 illustrates a flow rate distribution of the coolant gas in the chamber 10 of the wafer-cooling apparatus 1 in which the coolant conduit assembly 40 includes the coolant conduits 43 which are formed with the arcuate slit holes 433 and which include the flow limiters 432 (see FIGS. 1 to 6). As shown in FIG. 11, an area (A2) occupied by the coolant gas having a highest flow rate is significantly greater than an area (A1) occupied by the coolant gas having a highest flow rate shown in FIG. 10. This result indicates that compared to the wafer-cooling apparatus 1 in which the coolant conduit assembly 40 disposed in the chamber 10 includes the coolant conduits 43′ formed with the circular holes 433′, the coolant gas having the highest flow rate can be distributed more evenly and thus the wafers (Wf) can be cooled more sufficiently in the chamber 10 of the wafer-cooling apparatus 1 in which the coolant conduit assembly 40 includes the coolant conduits 43 formed with the arcuate slit holes 433.

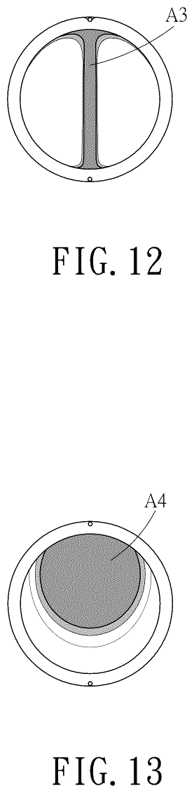

FIG. 12 illustrates a heat convection coefficient distribution on one of the wafers (Wf) cooled by the wafer-cooling apparatus 1 in which the coolant conduit assembly 40 disposed in the chamber 10 includes the coolant conduits 43′ formed with the circular holes 433′ (see FIG. 8). FIG. 13 illustrates a heat convection coefficient distribution on one of the wafers (Wf) cooled by the wafer-cooling apparatus 1 in which the coolant conduit assembly 40 disposed in the chamber 10 includes the coolant conduits 43 which are formed with the arcuate slit holes 433 and which include the flow limiters 432 (see FIGS. 1 to 6). As shown in FIG. 13, an area (A4) occupied by a highest heat convection coefficient is significantly greater than an area (A3) occupied by a highest heat convection coefficient shown in FIG. 12. These results indicate that compared to the wafer-cooling apparatus 1 in which the coolant conduit assembly 40 disposed in the chamber 10 includes the coolant conduits 43′ formed with the circular holes 433′, the area of the highest heat convection coefficient on each of the wafers (Wf) is increased significantly, and thus the wafers (Wf) are cooled more sufficiently in the chamber 10 of the wafer-cooling apparatus 1 in which the coolant conduit assembly 40 includes the coolant conduits 43 formed with the arcuate slit holes 433.

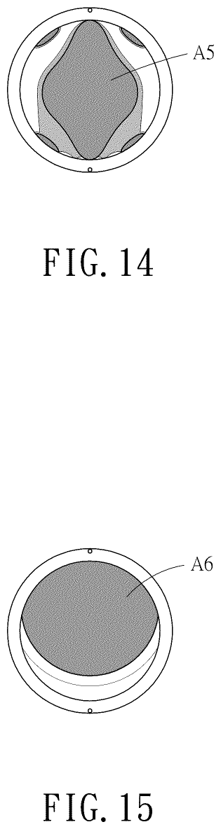

The wafer-cooling apparatus 1 in which the coolant conduit assembly 40 includes the first coolant conduit 43a and the second coolant conduit 43b with the arcuate slit holes 433 of the first coolant conduit 43a being staggered from the arcuate slit holes 433 of the second coolant conduit 43b, the wafer-cooling apparatus 1 in which the coolant conduit assembly 40 only includes the first coolant conduit 43a formed with the arcuate slit holes 433, and the wafer-cooling apparatus 1 in which the coolant conduit assembly 40 includes the first coolant conduit 43a and the second coolant conduit 43b with the arcuate slit holes 433 of the first coolant conduit 43a being registered with the arcuate slit holes 433 of the second coolant conduit 43b are subjected to a heat convection coefficient distribution analysis. The results are shown in FIGS. 14 to 16.

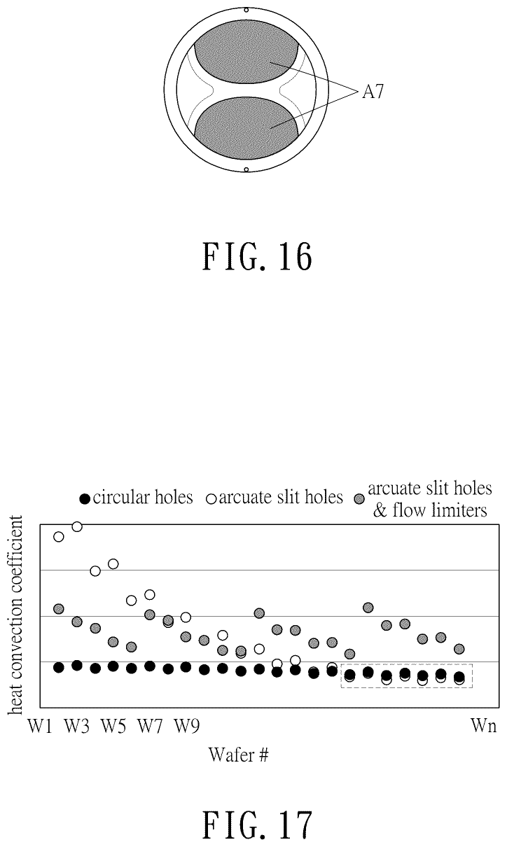

FIG. 14 illustrates a heat convection coefficient distribution on one of the wafers (Wf) cooled by the wafer-cooling apparatus 1 in which the coolant conduit assembly 40 includes the first coolant conduit 43a and the second coolant conduit 43b with the arcuate slit holes 433 of the first coolant conduit 43a being staggered from the arcuate slit holes 433 of the second coolant conduit 43b. FIG. 15 illustrates a heat convection coefficient distribution on one of the wafers (Wf) cooled by the wafer-cooling apparatus 1 in which the coolant conduit assembly 40 only includes the first coolant conduit 43a formed with the arcuate slit holes 433. FIG. 16 illustrates a heat convection coefficient distribution on one of the wafers (Wf) cooled by the wafer-cooling apparatus 1 in which the coolant conduit assembly 40 includes the first coolant conduit 43a and the second coolant conduit 43b with the arcuate slit holes 433 of the first coolant conduit 43a being registered with the arcuate slit holes 433 of the second coolant conduit 43b. In comparison with an area (A6) occupied by a highest heat convection coefficient shown in FIG. 15 and an area (A7) occupied by a highest heat convection coefficient shown in FIG. 16, an area (A5) occupied by a highest heat convection coefficient shown in FIG. 14 is more evenly distributed on the one of the wafers (Wf). These results indicate that compared to the wafer-cooling apparatus 1 in which the coolant conduit assembly 40 only includes the first coolant conduit 43a formed with the arcuate slit holes 433 and the wafer-cooling apparatus 1 in which the coolant conduit assembly 40 includes the first coolant conduit 43a and the second coolant conduit 43b with the arcuate slit holes 433 of the first coolant conduit 43a being registered with the arcuate slit holes 433 of the second coolant conduit 43b, an area occupied by a highest heat convection coefficient is more evenly distributed on each of the wafers (Wf), and thus the wafers (Wf) can be cooled more sufficiently in the chamber 10 of the wafer-cooling apparatus 1 in which the coolant conduit assembly 40 includes the first coolant conduit 43a and the second coolant conduit 43b with the arcuate slit holes 433 of the first coolant conduit 43a being staggered from the arcuate slit holes 433 of the second coolant conduit 43b (see FIGS. 1 and 2).

The wafer-cooling apparatus 1 in which the coolant conduit assembly 40 includes the coolant conduits 43 which include the flow limiters 432 and which are formed with the arcuate slit holes 433 (see FIGS. 1 to 7), the wafer-cooling apparatus 1 in which the coolant conduit assembly 40 includes the coolant conduits 43′ formed with the circular holes 433′ (see FIG. 8), and the wafer-cooling apparatus 1 in which the coolant conduit assembly 40 includes the coolant conduits 43 formed with the arcuate slit holes 433 but without the flow limiters 432 (see FIG. 9) are subjected to a heat convection coefficient distribution analysis. The results are shown in FIG. 17, in which W1 represents an uppermost one of the wafers (Wf) mounted on the support members of the wafer boat 30 and Wn represents a lowermost one of the wafers (Wf) mounted on the support members of the wafer boat 30.

As shown in FIG. 17, compared to the heat convection coefficients on the wafers (Wf) cooled by the wafer-cooling apparatus 1 in which the coolant conduit assembly 40 includes the coolant conduits 43′ formed with the circular holes 433′, the heat convection coefficients on most of the wafers (Wf) cooled by the wafer-cooling apparatus 1 in which the coolant conduit assembly 40 includes the coolant conduits 43 formed with the arcuate slit holes 433 but without the flow limiters 432 are increased, and the heat convection coefficients on all of the wafers (Wf) cooled by the wafer-cooling apparatus 1 in which the coolant conduit assembly 40 includes the coolant conduits 43 which are formed with the arcuate slit holes 433 and which include the flow limiters 432 are increased more significantly. These results indicate that the wafers (Wf) can be cooled more sufficiently in the wafer-cooling apparatus 1 in which the coolant conduit assembly 40 includes the coolant conduits 43 which are formed with the arcuate slit holes 433 and which include the flow limiters 432.

In the present disclosure, a coolant conduit assembly for a wafer-cooling apparatus includes a plurality of coolant conduits, each of which includes a plurality of tubular walls displaced from one another in a direction of a tubular axis, and a plurality of flow limiters alternated with and connected to the plurality of tubular walls in the direction of the tubular axis. Each of the tubular walls includes at least one arcuate slit hole, and an inner diameter of each of the flow limiters is smaller than an inner diameter of each of the tubular walls. Wafers subjected to a high temperature process (for example, but not limited to, a wet etching process at an elevated temperature) can be cooled sufficiently in the wafer-cooling apparatus including the coolant conduit assembly.

In accordance with some embodiments of the present disclosure, a coolant conduit is adapted for a cooling apparatus which includes a chamber having an accommodation space, a coolant inlet disposed to be in fluid communication with the accommodation space, and a wafer boat disposed in the accommodation space. The coolant conduit includes at least one tubular wall and at least one arcuate slit hole. The at least one tubular wall is disposed outwardly and radially from the wafer boat in the chamber. The at least one tubular wall includes an inner wall surface and an outer wall surface opposite to each other in radial directions. The inner wall surface surrounds a tubular axis and defines a passage extending upwardly to terminate at an upper end surface formed with an opening that is adapted to be in fluid communication with the coolant inlet. The at least one arcuate slit hole is formed in the outer wall surface to confront the wafer boat and extends from the outer wall surface into the inner wall surface along a first radial line to be in fluid communication with the accommodation space. The at least one arcuate slit hole has a height and a width. A ratio of the width to the height is greater than about 1.

In accordance with some embodiments of the present disclosure, the at least one arcuate slit hole extends along the tubular axis to terminate at an upper surface and a lower surface that define the height, and extends about the tubular axis to terminate at a first side surface and a second side surface. The first side surface forms a first joining line with the inner wall surface. The second side surface forms a second joining line with the inner wall surface. The first joining line and the second joining line form a chord line that is perpendicular to the first radial line and that defines the width.

In accordance with some embodiments of the present disclosure, the ratio of the width to the height is less than about 11.5.

In accordance with some embodiments of the present disclosure, the first side surface and the second side surface are in a same plane.

In accordance with some embodiments of the present disclosure, the first joining line and the tubular axis define a second radial line. The first radial line and the second radial line form an included angle that is greater than about 10.5° and less than about 90.5°.

In accordance with some embodiments of the present disclosure, the at least one tubular wall has an inner diameter. The coolant conduit further includes at least one flow limiter which is connected to the at least one tubular wall in the direction of the tubular axis, and which has an inner diameter smaller than the inner diameter of the at least one tubular wall.

In accordance with some embodiments of the present disclosure, a ratio of the inner diameter of the at least one flow limiter to the inner diameter of the at least one tubular wall is greater than about 0.5 and less than about 1.

In accordance with some embodiments of the present disclosure, the at least one tubular wall includes a plurality of tubular walls displaced from one another in the direction of the tubular axis. Each of the plurality of tubular walls has an inner diameter. The coolant conduit further includes a plurality of flow limiters alternated with and connected to the plurality of tubular walls in the direction of the tubular axis. Each of the plurality of flow limiters has an inner diameter smaller than the inner diameter of each of the plurality of tubular walls.

In accordance with some embodiments of the present disclosure, each of the plurality of tubular walls includes the at least one arcuate slit hole.

In accordance with some embodiments of the present disclosure, the number of at least one arcuate slit hole in each of the plurality of tubular walls ranges from about 1 to about 3.

In accordance with some embodiments of the present disclosure, a total number of the at least one arcuate slit hole of the coolant conduit ranges from about 20 to about 50.

In accordance with some embodiments of the present disclosure, the plurality of flow limiters have gradually reduced inner diameters in a downstream direction.

In accordance with some embodiments of the present disclosure, a cooling apparatus includes a chamber, a coolant inlet, a wafer boat, and a coolant conduit. The chamber has an accommodation space. The coolant inlet is disposed to be in fluid communication with the accommodation space. The wafer boat is disposed in the accommodation space. The coolant conduit is disposed in the chamber, and includes at least one tubular wall and at least one arcuate slit hole. The at least one tubular wall is disposed outwardly and radially from the wafer boat, and includes an inner wall surface and an outer wall surface opposite to each other in radial directions. The inner wall surface surrounds a tubular axis and defines a passage extending upwardly to terminate at an upper end surface formed with an opening that is in fluid communication with the coolant inlet. The at least one arcuate slit hole is formed in the outer wall surface to confront the wafer boat and extends from the outer wall surface into the inner wall surface along a first radial line to be in fluid communication with the accommodation space. The at least one arcuate slit hole has a height and a width. A ratio of the width to the height is greater than about 1.

In accordance with some embodiments of the present disclosure, the ratio of the width to the height is less than about 11.5.

In accordance with some embodiments of the present disclosure, the at least one arcuate slit hole extends along the tubular axis to terminate at an upper surface and a lower surface that define the height, and extends about the tubular axis to terminate at a first side surface and a second side surface. The first side surface forms a first joining line with the inner wall surface. The second side surface forms a second joining line with the inner wall surface. The first joining line and the second joining line form a chord line that is perpendicular to the first radial line and that defines the width. The first joining line and the tubular axis define a second radial line. The first radial line and the second radial line form an included angle that is greater than about 10.5° and less than about 90.5°.

In accordance with some embodiments of the present disclosure, the at least one tubular wall has an inner diameter. The coolant conduit further includes at least one flow limiter which is connected to the at least one tubular wall in the direction of the tubular axis, and which has an inner diameter smaller than the inner diameter of the at least one tubular wall.

In accordance with some embodiments of the present disclosure, a cooling apparatus includes a chamber, a coolant inlet, a wafer boat, and a plurality of coolant conduits. The chamber has an accommodation space extending in a direction of a central axis. The coolant inlet is disposed to be in fluid communication with the accommodation space. The wafer boat is disposed in the accommodation space to mount a plurality of wafers displaced from one another by a plurality of interval spaces along the central axis. The coolant conduits are disposed in the chamber and angularly spaced apart from one another. Each of the coolant conduits includes at least one tubular wall and at least one arcuate slit hole. The at least one tubular wall is disposed outwardly and radially from the wafer boat, and includes an inner wall surface and an outer wall surface opposite to each other in radial directions. The inner wall surface surrounds a tubular axis and defines a passage extending upwardly to terminate at an upper end surface formed with an opening that is in fluid communication with the coolant inlet. The at least one arcuate slit hole is formed in the outer wall surface to confront the wafer boat and extends from the outer wall surface into the inner wall surface along a first radial line to be in fluid communication with the accommodation space. The at least one arcuate slit hole extends along the tubular axis to terminate at an upper surface and a lower surface that define a height of the at least one arcuate slit hole, and extends about the tubular axis to terminate at a first side surface and a second side surface. The first side surface forms a first joining line with the inner wall surface. The second side surface forms a second joining line with the inner wall surface. The first joining line and the second joining line form a chord line that is perpendicular to the first radial line and that defines a width of the at least one arcuate slit hole. A ratio of the width to the height is greater than about 1.

In accordance with some embodiments of the present disclosure, the plurality of coolant conduits include a first coolant conduit and a second coolant conduit which are disposed to be diametrically opposite to each other.

In accordance with some embodiments of the present disclosure, the at least one arcuate slit hole of the first coolant conduit includes a plurality of arcuate slit holes displaced from one another in a direction of a conduit axis of the first coolant conduit. The at least one arcuate slit hole of the second coolant conduit includes a plurality of arcuate slit holes displaced from one another in a direction of a conduit axis of the second coolant conduit. The plurality of arcuate slit holes of the first coolant conduit are staggered from the plurality of arcuate slit holes of the second coolant conduit.

In accordance with some embodiments of the present disclosure, each of the plurality of arcuate slit holes of the first coolant conduit registers with a corresponding one of the plurality of interval spaces. Rach of the plurality of arcuate slit holes of the second coolant conduit registers with a corresponding one of the plurality of interval spaces.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A coolant conduit for a cooling apparatus which includes a chamber having an accommodation space, a coolant inlet disposed to be in fluid communication with the accommodation space, and a wafer boat disposed in the accommodation space, the coolant conduit comprising:
at least one tubular wall disposed outwardly and radially from the wafer boat in the chamber, the at least one tubular wall including an inner wall surface and an outer wall surface opposite to each other in radial directions, the inner wall surface surrounding a tubular axis and defining a passage extending upwardly to terminate at an upper end surface formed with an opening that is adapted to be in fluid communication with the coolant inlet; and
at least one arcuate slit hole formed in the outer wall surface to confront the wafer boat and extending from the outer wall surface into the inner wall surface along a first radial line to be in fluid communication with the accommodation space, the at least one arcuate slit hole having a height and a width, a ratio of the width to the height being greater than 1.

2. The coolant conduit as claimed in claim 1, wherein the at least one arcuate slit hole extends along the tubular axis to terminate at an upper surface and a lower surface that define the height, and extends about the tubular axis to terminate at a first side surface and a second side surface, the first side surface forming a first joining line with the inner wall surface, the second side surface forming a second joining line with the inner wall surface, the first joining line and the second joining line forming a chord line that is perpendicular to the first radial line and that defines the width.

3. The coolant conduit as claimed in claim 1, wherein the ratio of the width to the height is less than 11.5.

4. The coolant conduit as claimed in claim 2, wherein the first side surface and the second side surface are in a same plane.

5. The coolant conduit as claimed in claim 2, wherein the first joining line and the tubular axis define a second radial line, the first radial line and the second radial line forming an included angle that is greater than 10.5° and less than 90.5°.

6. The coolant conduit as claimed in claim 1, wherein
the at least one tubular wall has an inner diameter; and
the coolant conduit further comprises at least one flow limiter which is connected to the at least one tubular wall in the direction of the tubular axis, and which has an inner diameter smaller than the inner diameter of the at least one tubular wall.

7. The coolant conduit as claimed in claim 6, wherein a ratio of the inner diameter of the at least one flow limiter to the inner diameter of the at least one tubular wall is greater than 0.5 and less than 1.

8. The coolant conduit as claimed in claim 1, wherein
the at least one tubular wall includes a plurality of tubular walls displaced from one another in the direction of the tubular axis, each of the plurality of tubular walls having an inner diameter; and
the coolant conduit further comprises a plurality of flow limiters alternated with and connected to the plurality of tubular walls in the direction of the tubular axis, each of the plurality of flow limiters having an inner diameter smaller than the inner diameter of each of the plurality of tubular walls.

9. The coolant conduit as claimed in claim 8, wherein each of the plurality of tubular walls includes the at least one arcuate slit hole.

10. The coolant conduit as claimed in claim 9, wherein the number of at least one arcuate slit hole in each of the plurality of tubular walls ranges from 1 to 3.

11. The coolant conduit as claimed in claim 10, wherein a total number of the at least one arcuate slit hole of the coolant conduit ranges from 20 to 50.

12. The coolant conduit as claimed in claim 8, wherein the plurality of flow limiters have gradually reduced inner diameters in a downstream direction.

13. A cooling apparatus, comprising:
a chamber having an accommodation space;
a coolant inlet disposed to be in fluid communication with the accommodation space;
a wafer boat disposed in the accommodation space; and
a coolant conduit disposed in the chamber and including:
at least one tubular wall disposed outwardly and radially from the wafer boat, and including an inner wall surface and an outer wall surface opposite to each other in radial directions, the inner wall surface surrounding a tubular axis and defining a passage extending upwardly to terminate at an upper end surface formed with an opening that is in fluid communication with the coolant inlet; and
at least one arcuate slit hole formed in the outer wall surface to confront the wafer boat and extending from the outer wall surface into the inner wall surface along a first radial line to be in fluid communication with the accommodation space, the at least one arcuate slit hole having a height and a width, a ratio of the width to the height being greater than 1.

14. The cooling apparatus as claimed in claim 13, wherein the ratio of the width to the height is less than 11.5.

15. The cooling apparatus as claimed in claim 13, wherein
the at least one arcuate slit hole extends along the tubular axis to terminate at an upper surface and a lower surface that define the height, and extends about the tubular axis to terminate at a first side surface and a second side surface, the first side surface forming a first joining line with the inner wall surface, the second side surface forming a second joining line with the inner wall surface, the first joining line and the second joining line forming a chord line that is perpendicular to the first radial line and that defines the width; and
the first joining line and the tubular axis define a second radial line, the first radial line and the second radial line forming an included angle that is greater than 10.5° and less than 90.5°.

16. The cooling apparatus as claimed in claim 13, wherein
the at least one tubular wall has an inner diameter; and
the coolant conduit further includes at least one flow limiter which is connected to the at least one tubular wall in the direction of the tubular axis, and which has an inner diameter smaller than the inner diameter of the at least one tubular wall.

17. A cooling apparatus, comprising:
a chamber having an accommodation space extending in a direction of a central axis;
a coolant inlet disposed to be in fluid communication with the accommodation space;
a wafer boat disposed in the accommodation space to mount a plurality of wafers displaced from one another by a plurality of interval spaces along the central axis; and
a plurality of coolant conduits disposed in the chamber and angularly spaced apart from one another, each of the plurality of coolant conduits including:
at least one tubular wall disposed outwardly and radially from the wafer boat, and including an inner wall surface and an outer wall surface opposite to each other in radial directions, the inner wall surface surrounding a tubular axis and defining a passage extending upwardly to terminate at an upper end surface formed with an opening that is in fluid communication with the coolant inlet; and
at least one arcuate slit hole formed in the outer wall surface to confront the wafer boat and extending from the outer wall surface into the inner wall surface along a first radial line to be in fluid communication with the accommodation space, the at least one arcuate slit hole extending along the tubular axis to terminate at an upper surface and a lower surface that define a height of the at least one arcuate slit hole, and extending about the tubular axis to terminate at a first side surface and a second side surface, the first side surface forming a first joining line with the inner wall surface, the second side surface forming a second joining line with the inner wall surface, the first joining line and the second joining line forming a chord line that is perpendicular to the first radial line and that defines a width of the at least one arcuate slit hole, a ratio of the width to the height being greater than 1.

18. The cooling apparatus as claimed in claim 17, wherein the plurality of coolant conduits include a first coolant conduit and a second coolant conduit which are disposed to be diametrically opposite to each other.

19. The cooling apparatus as claimed in claim 18, wherein
the at least one arcuate slit hole of the first coolant conduit includes a plurality of arcuate slit holes displaced from one another in a direction of a conduit axis of the first coolant conduit;
the at least one arcuate slit hole of the second coolant conduit includes a plurality of arcuate slit holes displaced from one another in a direction of a conduit axis of the second coolant conduit; and
the plurality of arcuate slit holes of the first coolant conduit are staggered from the plurality of arcuate slit holes of the second coolant conduit.

20. The cooling apparatus as claimed in claim 19, wherein
each of the plurality of arcuate slit holes of the first coolant conduit registers with a corresponding one of the plurality of interval spaces; and
each of the plurality of arcuate slit holes of the second coolant conduit registers with a corresponding one of the plurality of interval spaces.
